(19) United States
(12) Patent Application Publication
(10) Pub. No.: US 2025/0082128 A1
(43) Pub. Date: Mar. 13, 2025

(54) BEVERAGE PREPARATION WITH SIMPLE CAPSULE TRANSFER

(71) Applicant: SOCIETE DES PRODUITS NESTLE S.A., Vevey (CH)

(72) Inventors: MARCEL FANKHAUSER, Toffen (CH); GILLES GAVILLET, Ursy (CH); RUDOLF SCHENK, Konolfingen (CH)

(21) Appl. No.: 18/721,984

(22) PCT Filed: Dec. 21, 2022
(86) PCT No.: PCT/EP2022/087148

§ 371 Date: Jun. 20, 2024

(30) Foreign Application Priority Data
Dec. 22, 2021 (EP) 21216930.4

(51) Int. Cl. A47J 31/40; A47J 31/22; A47J 31/44

(52) U.S. Cl. CPC A47J 31/407; A47J 31/22; A47J 31/4403

(57) ABSTRACT

A machine (1) is configured to prepare a beverage from a capsule (5) having a body containing an ingredient The beverage is prepared by circulating a liquid into the capsule and centrifugally driving the capsule. The machine has a first capsule handler (10) and a second capsule handler (20) that are movable one relative to the other from a capsule transfer configuration to a capsule processing configuration for centrifuging the capsule (5) by rotation about a processing axis (30′) of the first and second capsule handlers (10,20). The machine has a capsule insertion passage (60) associated with one or more capsule insertion guides (61) configured to guide the capsule (5) towards a capsule holding position in a space (100′) between the first and second capsule handlers (10,20) in their transfer configuration. The capsule insertion guide(s) (61) comprise(s) at least a rotatable portion (38) that is stationary relative to at least one of the first and second capsule handlers (10,20) and rotates therewith when the first and second capsule handlers (10,20) are rotated for centrifugation.

### FIELD OF THE INVENTION

The field of the invention pertains to beverage preparation machines by centrifuging capsules containing an ingredient of the beverage to be prepared.

For the purpose of the present description, a “beverage” is meant to include any human-consumable liquid substance, such as tea, coffee, hot or cold chocolate, milk, soup, baby food, etc . . . . A “capsule” is meant to include any container such as a packaging for containing a pre-portioned beverage ingredient, e.g. a flavouring ingredient, the packaging forming an enclosure of any material, in particular an airtight or pervious material, porous or non-porous material, e.g. plastic, aluminium, recyclable and/or biodegradable packagings, and of any shape and structure, including soft pods or rigid cartridges for containing the ingredient.

### BACKGROUND ART

Certain beverage preparation machines use capsules containing ingredients to be extracted or to be dissolved and/or ingredients that are stored and dosed automatically in the machine or else are added at the time of preparation of the drink. Some beverage machines possess filling means that include a pump for liquid, usually water, which pumps the liquid from a source of water that is cold or indeed heated through heating means, e.g. a thermoblock or the like.

Especially in the field of coffee preparation, machines have been widely developed in which a capsule containing beverage ingredients is inserted in a brewing device. The brewing device is tightly closed about the capsule, water is injected at the first face of the capsule, the beverage is produced in the closed volume of the capsule and a brewed beverage can be drained from a second face of the capsule and collected into a receptacle such as a cup or glass.

Brewing devices have been developed to facilitate insertion of a “fresh” capsule and removal of the capsule upon use. Examples of such brewing devices are disclosed in EP 1 767 129, WO 2009/043630, WO 2005/004683 and WO 2007/135136. The preparation of a beverage by using centrifugation is also known. Examples of centrifugation processes and corresponding devices are disclosed in WO2008/148601, WO2008/148650, U.S. Pat. No. 5,566,605, WO 2013/007776, WO 2013/007779 and WO 2013/007780.

Irrespectively of the extraction process itself it has also been proposed to facilitate the handling of capsules by systems for extracting them, in particular by motorizing the opening and/or closure of the extraction system for inserting and/or removing a capsule. Examples of such systems are for example disclosed in EP 1 767 129, WO2009/113035, WO 2012/025258, WO 2012/025259, WO 2012/041605, WO 2013/127476, WO 2014/096122, WO 2014/096123 and EP2015185946.9.

The preparation of a beverage by using centrifugation is also known. Such beverage preparation includes: providing a beverage (flavoring) ingredient, e.g. as powder and/or leaves, in a capsule; circulating liquid into the capsule and rotating the capsule at sufficient speed to ensure interaction of the liquid with the ingredient while creating a gradient of pressure of liquid in the capsule. Such pressure increases gradually from the centre towards the periphery of the capsule. As liquid traverses the ingredient, e.g. coffee bed, extraction of the ingredient, e.g. coffee compounds, takes place and a liquid extract is obtained that flows out at the periphery of the capsule. Examples of such systems are disclosed in WO2008/148601, WO 2013/007776, WO 2013/007779, WO 2013/007780, WO 2017/046294, WO 2017/068134 and WO 2017/202746.

It has been proposed to prepare beverages by centrifugation along a horizontal axis.

WO 2015/173123 and WO 2015/173124 disclose a centrifugal brewing chamber formed between two enclosing parts that are relatively translatable between an open position and a closed position. The enclosing parts cooperate with a pair of jaws that are movable between a capsule holding position to hold a capsule between the enclosing parts in the open position and a capsule release position to release the capsule. The jaws are actuated by a first actuator and a second actuator that are activated by the enclosing parts during their the relative translation. The jaws guide a capsule into a position between the enclosing parts in the open position and immobilize the capsule thereinbetween. Then, when the enclosing parts are translated together to enclose the capsule, the jaws release the capsule so that the brewing chamber is formed about the capsule. The enclosing parts are rotated about a horizontal axis to centrifuge the capsule for preparing the beverage with the ingredient in the capsule. At the end of beverage preparation, centrifugation stops and the enclosing parts are relatively translated to the open position whereby the used capsule is allowed to drop from the enclosing parts. Then the jaws are brought back into their capsule holding position.

### SUMMARY OF THE INVENTION

The invention relates to a capsule processing machine for preparing a beverage from at least one ingredient. Normally such beverage is then dispensed to a user, e.g. to a user-cup or user-mug.

For instance, the machine is a coffee, tea, chocolate, cacao, milk or soup preparation machine. For example, the machine is arranged for preparing within a beverage processing module that includes the capsule holder, a beverage by passing hot or cold water or another liquid through a capsule held in the holder containing an ingredient, such as a flavouring ingredient, of the beverage to be prepared, such as ground coffee or tea or chocolate or cacao or milk powder.

Such beverage preparation typically includes the mixing of a plurality of beverage ingredients, e.g. water and milk powder, and/or the infusion of a beverage ingredient, such as an infusion of ground coffee or tea with water. One or more of such ingredients may be supplied in loose and/or agglomerate powder form and/or in liquid form, in particular in a concentrate form. A carrier or diluent liquid, e.g. water, may be mixed with such ingredient to form the beverage. Typically, a predetermined amount of beverage is formed and dispensed on user-request, which corresponds to a portion (e.g. a serving). The volume of such a serving may be in the range of 15 to 1000 ml such as 25 to 600 ml for instance 40 to 250 ml, e.g. the volume for filling a cup or mug, depending on the type of beverage. Formed and dispensed beverages may be selected from ristrettos, espressos, lungos, cappuccinos, café latte, americano coffees, teas, etc . . . . For example, a coffee machine may be configured for dispensing espressos, e.g. an adjustable volume of 20 to 60 ml per serving, and/or for dispensing lungos, e.g. a volume in the range of 70 to 200 ml per serving, and/or for dispensing americanos, e.g. a volume in the range of 150 to 750 ml.

An aspect of the invention relates to a capsule processing machine for preparing a beverage from a capsule having a body containing an ingredient. The beverage is prepared by circulating a liquid into such capsule and centrifugally driving such capsule.

The centrifugation process for preparing a beverage is known for example from EP 2 000 062, EP 2 155 020, EP 2 152 128, WO 2008/148646, WO 2009/106175, WO 2009/106589, WO 2010/026045, WO 2010/026053, WO 2010/066736, WO 2008/148650, WO 2008/148834, WO 2010/066705, WO 2010/063644, WO 2011/023711, WO 2014/096122 or WO 2014/096123.

Typically, the machine includes one or more of the following components:
a) a fluid system in fluid communication with the capsule during beverage preparation;
b) an in-line heater and/or cooler for thermally conditioning a flow of liquid circulated into the capsule or a batch heater and/or cooler for circulating thermally conditioned liquid from the batch heater and/or cooler to the capsule;
c) a pump for pumping liquid to the capsule, in particular a low pressure pump e.g. within the range of 1 to 5 bar, such as 1.5 to 3 bar;
d) a motor for driving the capsule in rotation during beverage preparation;
e) an electric control unit, in particular comprising a printed circuit board (PCB), for receiving instructions from a user via an input user-interface and for controlling the heater and/or cooler, pump and motor(s); and
f) one or more sensors for sensing at least one characteristic selected from characteristics of fluid system, the heater and/or cooler, the pump, a liquid tank, an ingredient collector, a flow of the liquid (e.g. by a flowmeter), a pressure of the liquid and a temperature of the liquid, and for communicating such characteristic(s) to the control unit.

Typically, the capsule has a body containing an ingredient and a peripherally projecting flange, e.g. a body in the shape of a cup and a lid covering the mouth of the cup and extending beyond the mouth to form the peripherally projecting flange.

The capsule may have a body that is symmetric or asymmetric, conical or frusto-conical or cylindrical or spherical or hemispherical or frusto-spherical, containing the ingredient, e.g. ground coffee, tea or cacao or another beverage ingredient.

The capsule may be of the type described above under the header “field of the invention”. The capsule may be a capsule that has a container-body, e.g. a generally cup-shaped or hemispherical or hemi-ellipsoidal body, having a flange to which a cover lid (or membrane) is attached, in particular sealed. Typically the capsule contains a beverage ingredient. Examples of suitable capsules are disclosed in WO 2008/148601, WO 2008/148604, WO 2008/148646, WO 2008/148650, WO 2008/148656, WO 2008/148834, WO 2011/141532, WO 2011/141535, WO 2013/072239, WO 2013/072297, WO 2013/072326, WO 2015/044400. The capsule may be of the variety commercialised by Nespresso under the brand Vertuo.

The machine has a first capsule handler and a second capsule handler that are movable one relative to the other from: a capsule transfer configuration for receiving the capsule by the first and second capsule handlers and/or releasing the capsule from the first and second capsule handlers; to a capsule processing configuration for centrifuging the capsule by rotation about a processing axis of the first and second capsule handlers; and vice versa.

The machine includes a capsule insertion passage associated with one or more capsule insertion guides configured to guide the capsule, such as a projecting capsule flange of the capsule, towards a capsule holding position in a space between the first and second capsule handlers in their transfer configuration. The space may be associated with a holding device, such as one or more stop members, e.g. stop members formed by or fixed to the insertion guide(s), configured to hold the capsule in the space prior to being held by at least one of the first and second capsule handlers relatively moving towards and/or into the capsule processing configuration. Suitable stop members are for example known from WO 2005/004683.

The machine has a machine frame and/or housing which is stationary when the first and second capsule handlers are rotated for centrifugation and which supports the first and second capsule handlers.

The frame and/or housing may include or be fixed to a bottom configured to rest on a support surface external to such machine when the first and second capsule handlers are rotated about the processing axis for centrifugation. The external support surface can be formed by a table top. The processing axis may be at a (positive or negative) angle relative to such bottom in the range of 0° to 80°, for instance of 0° to 45°, such as of 0° to 30°, e.g. of 0° to 15°, typically of substantially 0°.

The frame and/or housing can support a motor that is connected to at least one of the first and second capsule handlers. For instance, the motor is connected directly or via a transmission to the at least one of the support device, the first and second capsule handlers. Typically, such motor is connected by at least one of belts e.g. toothed belts, gears e.g. spur gears, and connecting rods, to the at least one of the support device, the first and second capsule handlers. Such motor can be configured to relatively move the first and second capsule handlers between their transfer and processing configurations and/or can be configured to rotate the first and second capsule handlers so as to centrifuge the capsule.

The capsule insertion guide(s) include(s) at least a rotatable portion that is stationary relative to at least one of the first and second capsule handlers and rotates therewith when the first and second capsule handlers are rotated for centrifugation. For example, the rotatable portion is formed by at least one of the first and second capsule handlers or is assembled thereto.

The capsule insertion guide(s) may have a non-rotatable portion that is stationary relative to the machine frame and/or housing when the first and second capsule handlers are rotated for centrifugation. For instance, the non-rotatable portion is stationary relative to the frame and/or housing when the first and second capsule handlers are relatively moved between the capsule transfer configuration and the capsule processing configuration. The non-rotatable portion may be formed by the machine frame and/or housing or being assembled thereto.

In such a configuration, the capsule insertion guide (or at least part thereof) is associated or integrated with the first or second rotatable handler. Hence, its mobility follows the mobility of the rotatable handler instead of forming a further entity in the system that requires proper mechanical and/or cinematic coordination with and dissociation from the rotatable handler.

The machine may include a handler support device for supporting the first and second capsule handlers.

The handler support device can be configured to be and remain angularly fixed relative to the first and second capsule handlers and to rotate therewith about the processing axis when the first and second capsule handlers are rotated for centrifugation.

The handler support device may be configured to be angularly fixed relative to the first and second capsule handlers in their transfer configuration.

Thus, the first and second capsule handlers and the capsule with the ingredient can be held by the rotating handler support and secured therein and rotate as a block. Hence the stress during the rotation resulting from imperfect alignment of the first and second capsule handlers and the capsule or its content between themselves and/or in relation with the processing axis and its effect on other parts of the machine may be minimised. For instance, stress of a closure force of the first and second capsule handlers about the capsule is not amplified by imperfect alignment of the first and second capsule handlers and the capsule or its content with the processing axis, especially at high rotational speed. This may conveniently lead to a reduction of vibrations during beverage preparation and wear of the machine, especially on bearing elements enabling the first and second capsule handlers to rotate in the machine. Avoiding vibrations due to imperfect alignment in parallel to rotations may also improve centrifugation of the capsule and ingredient processing inside the capsule.

The machine can include an actuator that is configured to actuate the first and/or second capsule handlers to relatively move the first and second capsule handlers between the capsule transfer and processing configurations. For instance, the actuator is connected to the machine frame and/or housing so as to remain stationary relative thereto when the first and second capsule handlers are rotated for centrifugation.

The actuator may include a motor or a handle pivotally mounted on a handle axis. The motor or the handle may cooperate with a translational transmission member, such as an actuator slide and/or a member controlled by the motor or the handle via a cam and cam follower connection. Such member may be directly or indirectly connected to the first and second capsule handlers for relatively moving the capsule handlers between the capsule transfer configuration and the capsule processing configuration.

The machine can include a driving device connected to the first and second capsule handlers to relatively move the capsule handlers between the capsule transfer configuration and the capsule processing configuration.

The driving device may be secured to the capsule handlers in the processing configuration by at least one of a lock, a friction stop and an over-centred lever or cam mechanism.

The driving device can include one or more of: levers e.g. levers assembled pivotally about pivoting axis in a knuckle joint arrangement; gears e.g. spur gears and/or racks e.g. spur racks; cams and cam followers; belts e.g. toothed belts; and driving slides.

The driving device may connect the first capsule handler and the second capsule handler via the handler support device. For instance, the first capsule handler or the second capsule handler is stationary relative to the handler support device, possibly fixed thereto or integral therewith.

The driving device may include the above driving slide(s), and optionally one or more transmission members connecting the driving slide(s) to the first and second capsule handlers, to relatively move the capsule handlers between the capsule transfer configuration and the capsule processing configuration. The driving slide(s) may be actuated by the abovementioned actuator, for instance by being connected to the abovementioned translational transmission member cooperating via a groove and pin with the driving slide(s).

The driving slide(s) can include a slide body bearing a pair of arms each delimiting a groove, the arms extending from the body in parallel or substantially in parallel to the processing axis along opposite sides of at least one of the first and second capsule handlers. For instance, the groove is delimited by a ridge or ledge projecting from the slide body, for example around the at least one of the first and second capsule handlers.

The first and second capsule handlers in their processing configuration may delimit a capsule processing chamber configured to enclose the capsule. For example, one capsule handler of the first and second capsule handlers forms a cavity shaped to receive the capsule and the other capsule handler of the first and second capsule handlers forms a lid configured to close the cavity in the processing configuration. The lid may be distant from the cavity in the transfer configuration, e.g. such as to provide sufficient space between the first and second capsule handlers for the capsule to be able to reach a position between the first and second capsule handlers in the transfer configuration and/or to be evacuated from such position.

At least one handler of the first and second capsule handlers may include or may be associated with an inlet for guiding a liquid carrier, e.g. water, to the capsule when the capsule is being centrifuged by rotation. For instance, the inlet is associated with a capsule inlet opener, e.g. an inlet piercing device, configured to open the capsule, such as a capsule opener that has a conduit for guiding the liquid carrier from the inlet into the capsule and/or a capsule opener that has an outer face delimiting a passage for guiding the liquid carrier from the inlet into the capsule.

At least one handler of the first and second capsule handlers can include or can be associated with an outlet for guiding the beverage from the capsule when the capsule is being centrifuged by rotation. For instance, the outlet is associated with a capsule outlet opener, e.g. an outlet piercing device, configured to open the capsule, such as a capsule opener that has a conduit for guiding the beverage from the capsule into the outlet and/or a capsule opener that has an outer face delimiting a passage for guiding the beverage from the capsule into the outlet.

One handler of the first and second capsule handlers may include or may be associated with both such inlet and outlet.

Examples of suitable outlets and inlets, e.g. leading into a beverage collector and then to a machine outlet, are disclosed in WO 2015/173123 and WO 2015/173124.

The capsule insertion passage can be covered by a lid or a gate when the first and second capsule handlers are rotated for centrifugation, e.g. when the first and second capsule handlers are in their capsule processing configuration. For instance, the lid or gate is formed by a or the abovementioned handle configured to relatively move the first and second capsule handlers between the capsule transfer and processing configurations.

The handler support device may be pivotally supported by the machine frame or housing via a first bearing, such as a ball or roller bearing or a magnetic or plain bearing, and via a second bearing, such as a second ball or roller bearing or a magnetic or plain bearing. The first and second bearings may be located spaced apart along the processing axis.

The first bearing can be located on a side of the handler support device that is closer to the first capsule handler than to the second capsule handler, the second bearing being located on a side of the support device that is closer to the second capsule handler than to the first capsule handler. The first and second bearings can be, e.g. located, at opposite ends of the support device.

The handler support device may have a substantially cylindrical shape extending along the processing axis and surrounding at least partly the first and second capsule handlers. For instance, the handler support device delimits one or two openings configured for passing the capsule into and/or out of the handler support device, e.g. via corresponding capsule inlet and/or outlet capsule passages, for example by passing the capsule transversally to the processing axis.

For instance, the capsules are collected in a capsule collector downstream the outlet capsule passage, as for example disclosed in WO 2009/074559 or WO 2009/135869.

The machine may have a positioning device configured to position at least one of the first and second capsule handlers at a predetermined angular position about the processing axis when the first and second capsule handlers are in the capsule transfer configuration, for instance when rotation of the first and second capsule handlers about the processing axis is at a stop.

The positioning device may have a mechanical position coupler, e.g. including a mechanical lock or stopper or break, such as a coupler that is uncoupled and/or deactivated during rotation of the first and second capsule handlers about the processing axis.

The positioning device can have a magnetic position coupler, such as a magnetic coupler having a connector stationary relative to the machine frame and/or housing. The stationary connector can be magnetically constrained with a connector that is fixed to or comprised by at least one of the first and second capsule handlers and the handler support device. For example, one connector of the connectors can be a magnetic field generating element, e.g. a permanent magnet or an electromagnet or a permanent magnet with an electromagnet configured to neutralize the permanent magnet when the first and second capsule handlers rotate about the processing axis, and the other connector of the connectors can have at least one of a ferromagnetic member, a permanent magnet and an electromagnet.

Another aspect of the invention relates to a system comprising a capsule processing machine as described above and a capsule having a body containing an ingredient. The capsule is handled by the capsule insertion guide(s) associated with the machine's capsule insertion passage, the rotatable portion of the insertion guide(s) being configured to rotate with the machine's first and second capsule handlers in their capsule processing configuration when the capsule is centrifuged.

A further aspect of the invention relates to a method of preparing in the above described machine a beverage from a capsule having a body containing an ingredient. The method comprises:
transferring the capsule to the first and second capsule handlers in their transfer configuration to receive the capsule via the capsule insertion guide(s) associated with the capsule insertion passage;
bringing the first and second capsule handlers into the capsule processing configuration; and
centrifuging the capsule handled by the first and second capsule handlers that are rotated with the capsule insertion guide(s) about the processing axis and circulating the liquid into the capsule to form the beverage.

Yet another aspect of the invention relates to a use of a capsule as the capsule for: the above described machine; implementing the above described system; or carrying out the above described method. The capsule is provided to be:
transferred to the first and second capsule handlers in their transfer configuration to receive the capsule via the capsule insertion guide(s) associated with the capsule insertion passage;
supported by the first and second capsule handlers in their capsule processing configuration; and
centrifuged while being handled by the first and second capsule handlers that are rotated with the capsule insertion guide(s) about the processing axis while the liquid is circulated into the capsule to form the beverage.

### BRIEF DESCRIPTION OF THE DRAWINGS

The invention will now be described with reference to the schematic drawings, wherein:

FIG. 1 is a cross-sectional side view of part of a machine in a capsule transfer configuration and a capsule insertion guide that has a rotatable portion according to the invention;

FIG. 2 is a cross-sectional view from above of part of the machine shown in FIG. 1;

FIG. 3 is a cross-sectional side view of part of the machine shown in FIG. 1 after it has been brought into the capsule processing configuration; and

FIG. 4 is a cross-sectional view from above of part of the machine shown in FIG. 1.

### DETAILED DESCRIPTION

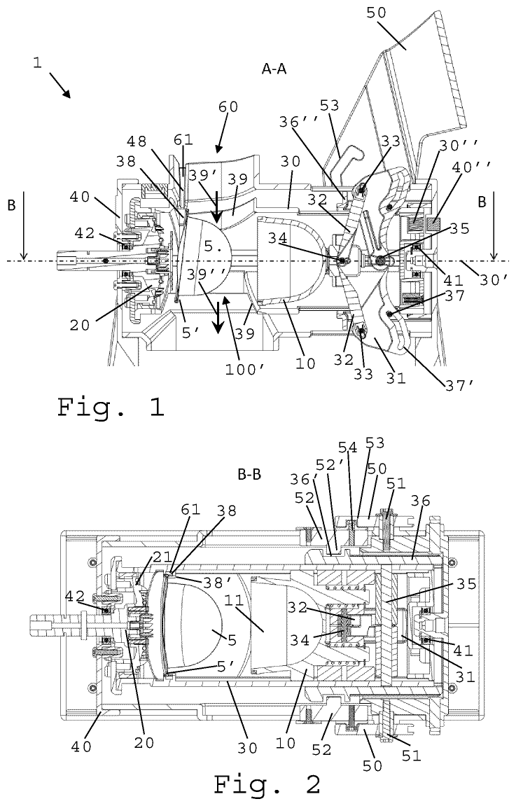

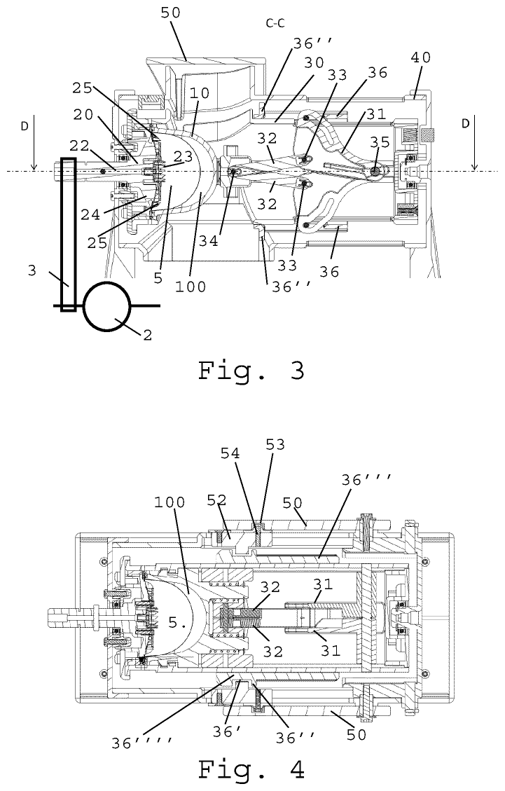

FIGS. 1 to 4 illustrate an exemplary embodiment of a machine 1 handling an ingredient capsule 5 having a body containing an ingredient, in accordance with the invention.

Beverage may be prepared by using machine 1 for instance by circulating a liquid, e.g. water such as thermally conditioned water, into capsule 5 and centrifugally driving capsule 5.

Machine 1 has a first capsule handler 10 and a second capsule handler 20 that are movable one relative to the other from:
a capsule transfer configuration for receiving capsule 5 by first and second capsule handlers 10,20 and/or releasing capsule 5 from first and second capsule handlers 10,20; to
a capsule processing configuration for centrifuging capsule 5 by rotation about a processing axis 30′ of first and second capsule handlers 10,20; and
vice versa.

Machine 1 includes a capsule insertion passage 60 associated with one or more capsule insertion guides 61 configured to guide capsule 5, such as a projecting capsule flange 5′ of capsule 5, towards a capsule holding position in a space 100′ between first and second capsule handlers 10,20 in their transfer configuration. For example, space 100′ is associated with a holding device, such as one or more stop members 38′ e.g. stop members 38′ formed by or fixed to insertion guide(s) 61, configured to hold capsule 5 in space 100′ prior to being held by at least one of first and second capsule handlers 10,20 relatively moving towards and/or into the capsule processing configuration.

Machine 1 is provided with a machine frame and/or housing 40 which is stationary when first and second capsule handlers 10,20 are rotated for centrifugation and which supports first and second capsule handlers 10,20.

Frame and/or housing 40 may include or be fixed to a bottom configured to rest on a support surface external to such machine 1 when first and second capsule handlers 10,20 are rotated about processing axis 30′ for centrifugation, e.g. an external support surface formed by a table top. Processing axis 30′ can be at an angle relative to such bottom in the range of 0° to 80°, for instance of 0° to 45°, such as of 0° to 30°, e.g. of 0° to 15°, typically of substantially 0°.

Frame and/or housing 40 may support a motor 2 that is connected to at least one of first and second capsule handlers 10,20, for instance connected directly or via a transmission 3 such as at least one of belts e.g. toothed belts, gears e.g. spur gears, and connecting rods.

Capsule insertion guide(s) 61 include(s) at least a rotatable portion 38 that is stationary relative to at least one of first and second capsule handlers 10,20 and rotates therewith when first and second capsule handlers 10,20 are rotated for centrifugation. For example, rotatable portion 38 is formed by first and/or second capsule handlers 10,20 or is assembled thereto.

Capsule insertion guide(s) 61 may include a non-rotatable portion 48 that is stationary relative to machine frame and/or housing 40 when first and second capsule handlers 10,20 are rotated for centrifugation. For example, non-rotatable portion 48 is stationary relative to frame and/or housing 40 when first and second capsule handlers 10,20 are relatively moved between the capsule transfer configuration and the capsule processing configuration, e.g. non-rotatable portion 48 being formed by machine frame and/or housing 40 or being assembled thereto.

Machine 1 can have a handler support device 30 for supporting first and second capsule handlers 10,20.

Handler support device 30 may be configured to be and remain angularly fixed relative to first and second capsule handlers 10,20 and to rotate therewith about processing axis 30′ when first and second capsule handlers 10,20 are rotated for centrifugation. For example, handler support device 30 is configured to be angularly fixed relative to the first and second capsule handlers 10,20 in their transfer configuration.

Machine 1 may include an actuator 50,51,52 that is configured to actuate first and/or second capsule handlers 10,20 to relatively move first and second capsule handlers 10,20 between the capsule transfer and processing configurations. For instance, actuator 50,51,52 is connected to machine frame and/or housing 40 so as to remain stationary relative thereto when first and second capsule handlers 10,20 are rotated for centrifugation.

The actuator can include a motor or a handle 50 that is pivotally mounted on a handle axis 51, the motor or handle 50 cooperating with a translational transmission member 52, such as an actuator slide 52 and/or a member 52 controlled by the motor or handle 50 via a cam 53 and cam follower 54 connection, directly or indirectly connected to first and second capsule handlers 10,20 for relatively moving capsule handlers 10,20 between the capsule transfer configuration and the capsule processing configuration.

Machine 1 may include a driving device 31,32,32,33,34,35,36 connected to first and second capsule handlers 10,20 to relatively move capsule handlers 10,20 between the capsule transfer configuration and the capsule processing configuration.

Driving device 31,32,32,33,34,35,36 may secure capsule handlers 10,20 in the processing configuration by at least one of a lock, a friction stop and an over-centred lever or cam mechanism 37,37′.

Driving device 31,32,32,33,34,35,36 can include one or more of: levers 31,32 e.g. levers assembled pivotally about pivoting axis 33,34,35 in a knuckle joint arrangement; gears e.g. spur gears and/or racks e.g. spur racks; cams and cam followers; belts e.g. toothed belts; and driving slides 36.

Driving device 31,32,32,33,34,35,36 may connect first capsule handler 10 and second capsule handler 20 via handler support device 30. For instance, the first capsule handler or second capsule handler 20 is stationary relative to handler support device 30.

Driving device 31,32,33,34,35,36 may include the abovementioned driving slide(s) 36, and optionally one or more transmission members 31,32,33,34,35 connecting driving slide(s) 36 to first and second capsule handlers 10,20, to relatively move capsule handlers 10,20 between the capsule transfer configuration and the capsule processing configuration. Driving slide(s) 36 can be actuated by the abovementioned actuator 50,51,52, for instance by being connected to the abovementioned translational transmission member 52 cooperating via a groove 36′ and pin 52′ with driving slide(s) 36.

Driving slide(s) 36 can have a slide body 36′″ bearing a pair of arms 36″″ each delimiting a groove 36′, arms 36″″ extending from body 36′″ in parallel or substantially in parallel to processing axis 30′ along opposite sides of at least one of first and second capsule handlers 10,20. For example, groove 36′ is delimited by a ridge or ledge 36″ projecting from slide body 36′″ e.g. around the at least one of the first and second capsule handlers 10,20.

First and second capsule handlers 10,20 in their processing configuration may delimit a capsule processing chamber 100 configured to enclose capsule 5. For example, one capsule handler 10 of first and second capsule handlers 10,20 forms a cavity 11 shaped to receive capsule 5 and the other capsule handler 20 of first and second capsule handlers 10,20 forms a lid 21 configured to close cavity 11 in processing configuration to secure capsule 5 in cavity 11, lid 21 being distant from cavity 11 in the transfer configuration, e.g. such as to provide sufficient space 100′ between first and second capsule handlers 10,20 for capsule 5 to be able to reach a position between first and second capsule handlers 10,20 in the transfer configuration and/or to be evacuated from such position.

At least one handler 20 of first and second capsule handlers 10,20 may include or may be associated with an inlet 22 for guiding a liquid carrier, e.g. water, to capsule 5 when capsule 5 is being centrifuged by rotation. For example, inlet 22 is associated with a capsule inlet opener, e.g. an inlet piercing device 23, configured to open capsule 5. The capsule opener can have a conduit for guiding the liquid carrier from inlet 22 into capsule 5. The capsule opener may have an outer face delimiting a passage for guiding the liquid carrier from the inlet into capsule.

At least one handler 20 of first and second capsule handlers 10,20 can include or be associated with an outlet 24 for guiding the beverage from capsule 5 when capsule 5 is being centrifuged by rotation. For example, outlet 24 is associated with a capsule outlet opener, e.g. an outlet piercing device 25, configured to open capsule 5. The capsule opener may have a conduit for guiding the beverage from the capsule into the outlet. The capsule opener can have an outer face delimiting a passage for guiding the beverage from the capsule into the outlet.

One handler 20 of first and second handlers 10,20 may include or being associated with both such inlet 22 and outlet 24.

Capsule insertion passage 60 may be covered by a lid or a gate when first and second capsule handlers 10,20 are rotated for centrifugation, e.g. when first and second capsule handlers 10,20 are in their capsule processing configuration. For example, the lid or gate is formed by a or the abovementioned handle 50 configured to relatively move first and second capsule handlers 10,20 between the capsule transfer and processing configurations.

Handler support device 30 can be pivotally supported by machine frame or housing 40 via a first bearing 41, such as a ball or roller bearing or a magnetic or plain bearing, and via a second bearing 42, such as a second ball or roller bearing or a magnetic or plain bearing. First and second bearings 41,42 may be located spaced apart along processing axis 30′.

First bearing 41 can be located on a side of handler support device 30 that is closer to the first capsule handler 10 than to second capsule handler 20. Second bearing 42 can be located on a side of support device 30 that is closer to second capsule handler 20 than to first capsule handler 10. For example, first and second bearings 41,42 are, e.g. located, at opposite ends of handler support device 30.

Handler support device 30 can have a substantially cylindrical shape extending along processing axis 30′ and surrounding at least partly first and second capsule handlers 10,20. For example, handler support device 30 delimits one or two openings 39 configured for passing capsule 5 into and/or out of handler support device 30 e.g. via corresponding capsule inlet and/or outlet capsule passages 39′,39″. For instance, capsule 5 is passed transversally to processing axis 30′.

Machine 1 can have a positioning device 30″,40″ configured to position at least one of the first and second capsule handlers 10,20 at a predetermined angular position about processing axis 30′ when first and second capsule handlers 10,20 are in the capsule transfer configuration, for instance when rotation of first and second capsule handlers 10,20 about the processing axis 30′ is at a stop.

Positioning device 30″,40″ may include a mechanical position coupler, e.g. including a mechanical lock or stopper or break, such as a coupler that is uncoupled and/or deactivated during rotation of first and second capsule handlers 10,20 about processing axis 30′.

Positioning device 30″,40″ can be provided with a magnetic position coupler, such as a magnetic coupler having a connector 40″ stationary relative to machine frame and/or housing 40. Stationary connector 40″ can be magnetically constrained with a connector 30″ that is fixed to or included in at least one of first and second capsule handlers 10,20 and handler support device 30. One connector 40″ of connectors 30″,40″ may be a magnetic field generating element, e.g. a permanent magnet or an electromagnet or a permanent magnet with an electromagnet configured to neutralize the permanent magnet when first and second capsule handlers 10,20 rotate about processing axis 30′. The other connector 30″ of connectors 30″,40″ may include at least one of a ferromagnetic member, a permanent magnet and an electromagnet.

1. A capsule processing machine for preparing a beverage from a capsule having a body containing an ingredient by circulating a liquid into such capsule and centrifugally driving such capsule, comprising:
a first capsule handler and a second capsule handler that are movable one relative to the other from:
a capsule transfer configuration for receiving said capsule by the first and second capsule handlers and/or releasing said capsule from the first and second capsule handlers; to
a capsule processing configuration for centrifuging said capsule by rotation about a processing axis of the first and second capsule handlers; and
a capsule insertion passage associated with one or more capsule insertion guides configured to guide said capsule towards a capsule holding position in a space between the first and second capsule handlers in their transfer configuration, for instance the space being associated with a holding device, such as one or more stop members configured to hold said capsule in the space prior to being held by at least one of the first and second capsule handlers relatively moving towards and/or into the capsule processing configuration,
a machine frame and/or housing which is stationary when the first and second capsule handlers are rotated for centrifugation and which supports the first and second capsule handlers,
the capsule insertion guide(s) comprise(s) at least a rotatable portion that is stationary relative to at least one of the first and second capsule handlers and rotates therewith when the first and second capsule handlers are rotated for centrifugation.

2. The machine of claim 1, wherein the capsule insertion guide(s) comprise(s) a non-rotatable portion that is stationary relative to the machine frame and/or housing when the first and second capsule handlers are rotated for centrifugation.

3. The machine of claim 1, which comprises a handler support device for supporting the first and second capsule handlers, the handler support device being configured to be and remain angularly fixed relative to the first and second capsule handlers and to rotate therewith about the processing axis when the first and second capsule handlers are rotated for centrifugation.

4. The machine of claim 1, which comprises an actuator that is configured to actuate the first and/or second capsule handlers to relatively move the first and second capsule handlers between the capsule transfer and processing configurations.

5. The machine of claim 1, which comprises a driving device connected to the first and second capsule handlers to relatively move the capsule handlers between the capsule transfer configuration and the capsule processing configuration.

6. The machine of claim 3, wherein a driving device connects the first capsule handler and the second capsule handler via the handler support device.

7. The machine of claim 6, wherein the driving device comprises said driving slide(s), and optionally one or more transmission members connecting the driving slide(s) to the first and second capsule handlers, to relatively move the capsule handlers between the capsule transfer configuration and the capsule processing configuration, the driving slide(s) being actuated by said actuator, for instance by being connected to said translational transmission member cooperating via a groove and pin with said driving slide(s).

8. The machine of claim 1, wherein:
the first and second capsule handlers in their processing configuration delimit a capsule processing chamber configured to enclose said capsule; and
at least one handler of the first and second capsule handlers comprises or is associated with an inlet for guiding a liquid carrier to said capsule when said capsule is being centrifuged by rotation.

9. The machine of claim 1, wherein the capsule insertion passage is covered by a lid or a gate when the first and second capsule handlers are rotated for centrifugation.

10. The machine of claim 3, wherein the handler support device is pivotally supported by the machine frame or housing via a first bearing.

11. The machine of claim 3, wherein the handler support device has a substantially cylindrical shape extending along the processing axis and surrounding at least partly the first and second capsule handlers.

12. The machine of claim 1, which has a positioning device configured to position at least one of the first and second capsule handlers at a predetermined angular position about the processing axis when the first and second capsule handlers are in the capsule transfer configuration.

13. A system comprising a capsule processing machine for preparing a beverage from a capsule having a body containing an ingredient by circulating a liquid into such capsule and centrifugally driving such capsule, comprising:
a first capsule handler and a second capsule handler that are movable one relative to the other from:
a capsule transfer configuration for receiving said capsule by the first and second capsule handlers and/or releasing said capsule from the first and second capsule handlers; to
a capsule processing configuration for centrifuging said capsule by rotation about a processing axis of the first and second capsule handlers; and
a capsule insertion passage associated with one or more capsule insertion guides configured to guide said capsule towards a capsule holding position in a space between the first and second capsule handlers in their transfer configuration, for instance the space being associated with a holding device, such as one or more stop members configured to hold said capsule in the space prior to being held by at least one of the first and second capsule handlers relatively moving towards and/or into the capsule processing configuration,
a machine frame and/or housing which is stationary when the first and second capsule handlers are rotated for centrifugation and which supports the first and second capsule handlers,
the capsule insertion guide(s) comprise(s) at least a rotatable portion that is stationary relative to at least one of the first and second capsule handlers and rotates therewith when the first and second capsule handlers are rotated for centrifugation and a capsule having a body containing an ingredient, the capsule being handled by the capsule insertion guide(s) associated with the machine's capsule insertion passage, the rotatable portion of the insertion guide(s) being configured to rotate with the machine's first and second capsule handlers in their capsule processing configuration when the capsule is centrifuged.

14. A method of preparing in a machine a beverage from a capsule having a body containing an ingredient by circulating a liquid into such capsule and centrifugally driving such capsule, comprising:
a first capsule handler and a second capsule handler that are movable one relative to the other from:
a capsule transfer configuration for receiving said capsule by the first and second capsule handlers and/or releasing said capsule from the first and second capsule handlers; to
a capsule processing configuration for centrifuging said capsule by rotation about a processing axis of the first and second capsule handlers; and
a capsule insertion passage associated with one or more capsule insertion guides configured to guide said capsule towards a capsule holding position in a space between the first and second capsule handlers in their transfer configuration, for instance the space being associated with a holding device, such as one or more stop members configured to hold said capsule in the space prior to being held by at least one of the first and second capsule handlers relatively moving towards and/or into the capsule processing configuration,
a machine frame and/or housing which is stationary when the first and second capsule handlers are rotated for centrifugation and which supports the first and second capsule handlers,
the capsule insertion guide(s) comprise(s) at least a rotatable portion that is stationary relative to at least one of the first and second capsule handlers and rotates therewith when the first and second capsule handlers are rotated for centrifugation, a beverage from a capsule having a body containing an ingredient, the method comprising:
transferring the capsule to the first and second capsule handlers in their transfer configuration to receive the capsule via the capsule insertion guide(s) associated with the capsule insertion passage;
bringing the first and second capsule handlers into the capsule processing configuration; and
centrifuging the capsule handled by the first and second capsule handlers that are rotated with the capsule insertion guide(s) about the processing axis and circulating the liquid into the capsule to form the beverage.

15. (canceled)
